(19) United States
(12) Patent Application Publication
(10) Pub. No.: US 2026/0227764 A1
(43) Pub. Date: Aug. 6, 2026

(54) SYSTEMS AND METHODS FOR THE LOCAL INCREMENTAL DEFORMATION OF LOCAL COMPONENT REGIONS

(71) Applicant: Ohio State Innovation Foundation, Columbus, OH (US)

(72) Inventors: Glenn DAEHN, Columbus, OH (US); Anupam VIVEK, Columbus, OH (US)

(21) Appl. No.: 19/150,410

(22) PCT Filed: Jan. 29, 2024
(86) PCT No.: PCT/US2024/013301

§ 371 Date: Jul. 23, 2025

Related U.S. Application Data
(60) Provisional application No. 63/481,836, filed on Jan. 27, 2023.

(51) Int. Cl. G05B 19/418; B21J 5/00; B21J 7/14

(52) U.S. Cl. CPC G05B 19/41815; B21J 5/002; B21J 7/14; G05B 2219/37584

(57) ABSTRACT

In one aspect, a method for plastic deformation is provided (300). The method includes: receiving a object to be processed (310); selecting at least one hammer (320); selecting an impact energy for the at least one hammer (330); selecting a drive mechanism (340); and deforming the object using the at least one hammer using the selected impact energy by the selected dive mechanism (350). The method further includes selecting a robot based on the selected drive mechanism and deforming the plastic object by the selected robot.

### CROSS REFERENCE TO RELATED APPLICATIONS

This application claims priority to U.S. Provisional Patent Application Ser. No. 63/481,836, filed on Jan. 27, 2023, and titled “SYSTEM FOR THE LOCAL INCREMENTAL PLASTIC DEFORMATION LOCAL COMPONENT REGIONS,” the contents of which are hereby incorporated by reference in their entireties.

### GOVERNMENT SUPPORT CLAUSE

This invention was made with government support under project number 2133630 awarded by the National Science Foundation. The government has certain rights in the invention.

### BACKGROUND

Deformation processing and thermal-mechanical processing are common methods to improve the structure and properties of metallic materials. Deformation can reduce porosity, break up large microstructural constituents, modify residual stress and store energy in the structure in the form of work hardening. This work hardened structure is harder, and the stored energy can promote recrystallization. Also, as plastic deformation is defined as the permanent change in shape, this can also be used to shape components to required dimensional tolerances and surface conditions. These are all important tools in the development of materials with excellent properties.

It is noted that while local plastic deformation is commonly used to control residual stress and microstructure, the current methods have significant limitations. Modern peening uses small energies per strike and methods such as rolling are difficult to implement in general applications. Here it is shown the surprising application that high energy per strike hammering can provide to actual structures along with a practical pathway to developing such systems.

There is a long history in using hammering, peening, burnishing, and rolling to improve local material microstructure and properties. There has been particular interest in using local plastic deformation during the deposition of wire arc additively manufactured components. This has been shown to improve microstructure and residual stress states in particular.

A few contemporary methods of local plastic deformation are used in conjunction with robotics for spatial control. Those described here include use of relatively high frequency low-amplitude low energy hammers. Energies per impact are usually not usually calculated in design or reported. Frequencies are usually over 10-1000 hz and the hammer tool is often always in contact with the body being deformed. The impact end of these tools is typically quite small, providing a deformed zone of a few millimeters or less. While this is called ‘hammering’ it does not follow our usual intuitive definition that includes large amounts of energy dissipated with each strike. Low energy per strike tools are often used because they are deemed compatible with robotic systems. Hammers with significant impact are avoided because there is a perception that they will damage the robotic system. As a result of this design choice, these systems have shallow depths of deformation, low deformation strains and therefore are not terribly effective at improving the material. Rollers are another class of deformation processing that has been used for local deformation; however, this often requires large, fixed tooling and as a result is difficult to use in a flexible or agile processing system.

### SUMMARY

In one aspect, a method for inducing plastic deformation in a body being manufactured is provided. The method includes: receiving a deformable object to be processed; selecting at least one hammer; selecting an impact energy for the at least one hammer; selecting a drive mechanism; and deforming the object using the at least one hammer using the selected impact energy by the selected dive mechanism. The method further includes selecting a robot based on the selected drive mechanism and deforming the object by the selected robot. Advantages of the method include the use of larger energies than in previous methods, and the avoidance of transmitting large forces to the robot.

In some aspects, the techniques described herein relate to a method for local plastic deformation including: receiving an object to be processed by a computing device; selecting at least one hammer of a plurality of hammers by the computing device; selecting an impact energy for the selected at least one hammer by the computing device; selecting a drive mechanism of a plurality of drive mechanisms by the computing device; and deforming the object using the at least one hammer, the selected impact energy, and the selected dive mechanism by the computing device.

In some aspects, the techniques described herein relate to a method, wherein selecting the at least one hammer includes selecting a mass and a punch tip for the at least one hammer.

In some aspects, the techniques described herein relate to a method, wherein the selecting the punch tip includes selecting the punch tip based on a size of the object.

In some aspects, the techniques described herein relate to a method, further including selecting the impact energy based on a flow stress of the object.

In some aspects, the techniques described herein relate to a method, wherein the drive mechanism includes a solenoid, pneumatic drive, linear motor, or a rotary motor.

In some aspects, the techniques described herein relate to a method, wherein selecting the at least one hammer includes selecting two hammers.

In some aspects, the techniques described herein relate to a method, further including selecting a robot based on the selected drive mechanism and deforming the plastic object by the selected robot.

In some aspects, the techniques described herein relate to a method, wherein the robot determines a deformation zone where to deform the object using the at least one hammer, the selected impact energy, and the selected dive mechanism.

In some aspects, the techniques described herein relate to a system local plastic deformation including: one or more processors; a computer-readable medium with computer-executable instructions stored thereon that when executed by the one or more processors cause the one or more processors to: receive an object to be processed; select at least one hammer of a plurality of hammers; select an impact energy for the selected at least one hammer; select a drive mechanism of a plurality of drive mechanisms; and deform the object using the at least one hammer, the selected impact energy, and the selected dive mechanism.

In some aspects, the techniques described herein relate to a system, wherein selecting the at least one hammer includes selecting a mass and a punch tip for the at least one hammer.

In some aspects, the techniques described herein relate to a system, wherein the selecting the punch tip includes selecting the punch tip based on a size of the object.

In some aspects, the techniques described herein relate to a system, further including selecting the impact energy based on a flow stress of the object.

In some aspects, the techniques described herein relate to a system, wherein the drive mechanism includes a solenoid, pneumatic drive, linear motor, or a rotary motor.

In some aspects, the techniques described herein relate to a system, wherein selecting the at least one hammer includes selecting two hammers.

In some aspects, the techniques described herein relate to a system, further including selecting a robot based on the selected drive mechanism and deforming the plastic object by the selected robot.

In some aspects, the techniques described herein relate to a system, wherein the robot determines a deformation zone where to deform the object using the at least one hammer, the selected impact energy, and the selected dive mechanism.

In some aspects, the techniques described herein relate to a non-transitory computer-readable medium with computer-executable instructions stored thereon that when executed by the one or more processors cause the one or more processors to: receive an object to be processed; select at least one hammer of a plurality of hammers; select an impact energy for the selected at least one hammer; select a drive mechanism of a plurality of drive mechanisms; and deform the object using the at least one hammer, the selected impact energy, and the selected dive mechanism.

In some aspects, the techniques described herein relate to a computer-readable medium, wherein selecting the at least one hammer includes selecting a mass and a punch tip for the at least one hammer.

In some aspects, the techniques described herein relate to a computer-readable medium, wherein the selecting the punch tip includes selecting the punch tip based on a size of the object.

In some aspects, the techniques described herein relate to a computer-readable medium, further including selecting the impact energy based on a flow stress of the object.

### BRIEF DESCRIPTION OF THE DRAWINGS

The accompanying figures, which are incorporated herein and form part of the specification, illustrate a malware detection system and method. Together with the description, the figures further serve to explain the principles of the malware detection system and method described herein and thereby enable a person skilled in the pertinent art to make and use the malware detection system and method.

FIG. 1 is an illustration of an example deformation system;

FIG. 2A is an illustration of example deformation system using a single hammer;

FIG. 2B is an illustration of example deformation system using multiple hammers;

FIG. 3 is an illustration of an example method for deforming an object using the deformation system; and

FIG. 4 shows an exemplary computing environment in which example embodiments and aspects may be implemented.

### DETAILED DESCRIPTION

In the following description, specific details are set forth describing some embodiments consistent with the present disclosure. Numerous specific details are set forth in order to provide a thorough understanding of the embodiments. It will be apparent, however, to one skilled in the art that some embodiments may be practiced without some or all of these specific details. The specific embodiments disclosed herein are meant to be illustrative but not limiting. One skilled in the art may realize other elements that, although not specifically described here, are within the scope and the spirit of this disclosure. In addition, to avoid unnecessary repetition, one or more features shown and described in association with one embodiment may be incorporated into other embodiments unless specifically described otherwise or if the one or more features would make an embodiment non-functional. In some instances, well known methods, procedures, components, and circuits have not been described in detail so as not to unnecessarily obscure aspects of the embodiments.

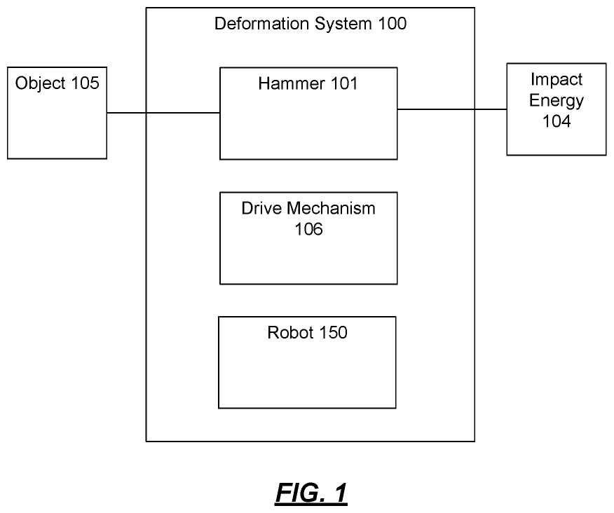

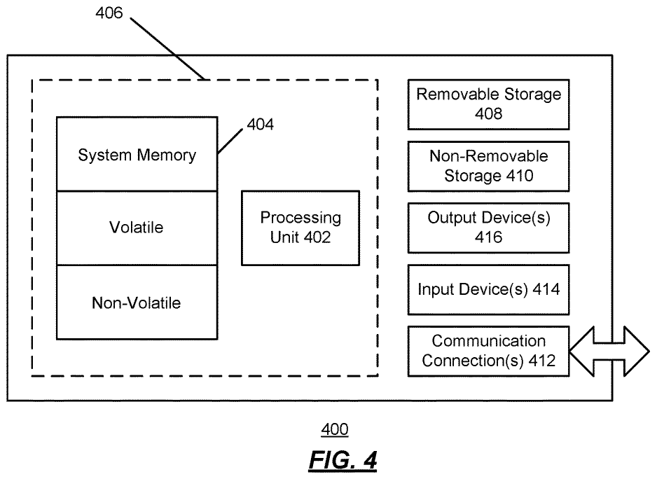

FIG. 1 is an illustration of an example system for object deformation. In the example shown, the deformation system 100 includes a hammer 101, a drive mechanism 106, and a robot 150. The deformation system 100 and some or all of its components may be implemented together or separately using one or more general purpose computing devices such as the computing device 400 illustrated with respect to FIG. 4.

The deformation system 100 may deform or modify an object 105 using the hammer 101. Deformation is a shape change of the object 105 and can also provide increases in hardness of the object 105, reduction in porosity of the object 105, refinement of coarse phases of the object 105, development of residual stress in the object 105, and improvement of surface finish and configuration of the object 105.

The hammer 101 may be selected by the deformation system 100 from among a plurality of hammers 101 according to the deformations that are to be applied to the object 105. Example hammers 101 may include high-energy solenoid hammers 101. Other types of hammers 101 may include pneumatic hammers 101, hydraulic hammers 101, linear motor hammers 101, rotary motor hammers 101, and hammers 101 using launch mechanisms such as explosives, and rail guns. The object 105 may be a plastic object or a metal object. Other types of objects 105 may be supported.

As will described further below, the hammer 101 may include one or more punch tips or tips. Each punch tip may have a different shaped contacted area and mass, and may be selected by the deformation system 100 based on the desired deformation to apply to the object 105 as well as one or more characteristics of the object 105 such as strength and hardness. Example deformations may include a deformation to create a desired level of strain to accomplish hardening, or a deformation to create an acceptable surface.

The deformation system 100 may further include one or more drive mechanisms 106 that swings or applies the hammer 101 to the object 105. The deformation system 100 may select the drive mechanism 106 from a plurality of drive mechanisms 106 such as a solenoid. Other types of drive mechanisms 106 may be supported such as pneumatic, hydraulic, liner motors, rotary motors, and rail guns. The mass of the hammer 101 including the punch tip and the type of drive mechanism 106 used to deform the object 105 may affect the impact energy 104 of the hammer 101 on the object 105.

The deformation system 100 may further include a robot 150. The robot 150 may hold the object 105, and may cause the deformation system 100 to deform the object 105. In some embodiments, the robot 150 may be used for precise positioning of the deformation zone on the object 105. For example, the deformation system 100 may deform and object 105 using multiple impulses over an area like fish-scales to cover a surface, and the robot 150 may move the object 105 and/or the hammer 101. The robot 150 may include a vision system to assist in the deformation and/or moving of the object 105.

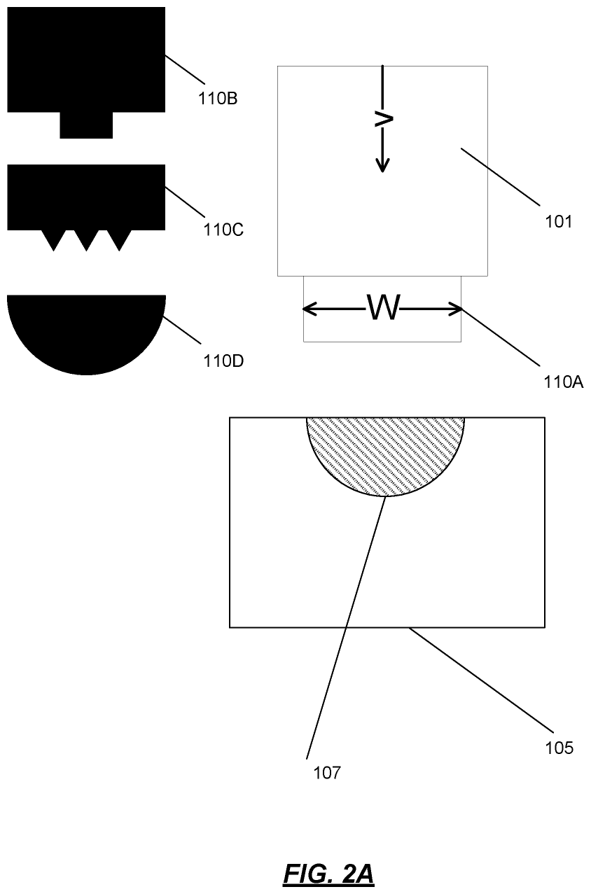

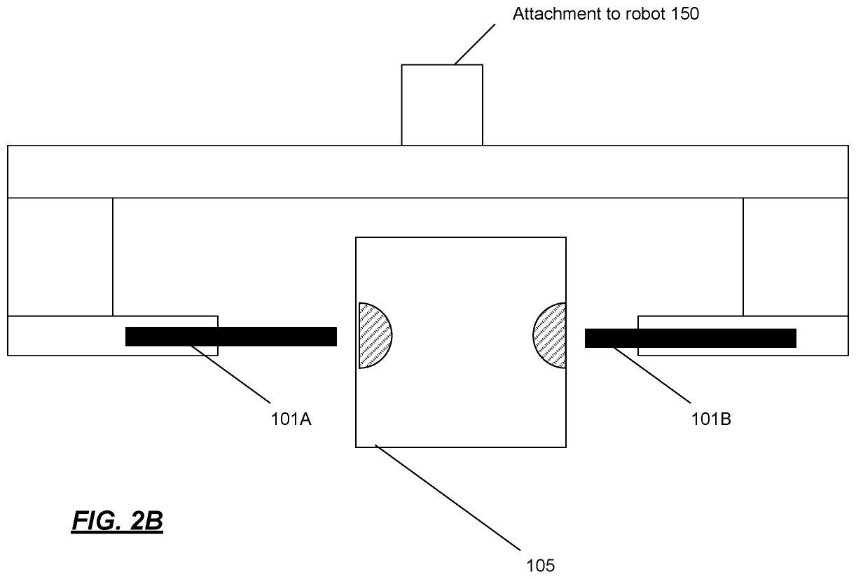

Once aspect to the invention is the use of relatively long-travel, low frequency tools that impact a larger area of the object 105 and an algorithm to design these tools. These tools (i.e., hammers 101) are usually controlled by kinetic energy, but they may also present a large enough pressure over a distance to develop plastic deformation. Example embodiments are illustrated in FIGS. 2A and 2B. In the case of a tool driven with kinetic energy, a hammer 101 with total mass m, is accelerated over some distance Dx to cause impact with the workpiece (i.e., object 105) at some velocity v. As shown in FIG. 2A, a single linear drive (i.e., the hammer 101) can be used, or opposed impactors may be used to increase total acceleration forces without transmitting them to a robot 150, as shown in FIG. 2B.

In FIG. 2A is shown an illustration of a hammer 101 with a mass m accelerated to impact a workpiece 105 at an interaction area 106. The workpiece 105 may be a plastic object, for example. The impact may be used to process weld area, fatigue susceptible fillet, or other features. The punch tips 110 (i.e., the punch tips 110A, 110B, 110C, and 110D) attached to the hammer 101 can be modified for a variety of effects on the workpiece 105. For example, a punch tip 110 could include an area that forces extensive plastic deformation and in successive overlapping steps, the divot from the central region could be minimized leaving a relatively smooth region on the workpiece 105.

In FIG. 2B is shown an illustration of using two opposing hammers 101 (i.e., the hammers 101A and 101B). Using opposing hammers 101 can be used to minimize forces onto the robot 150 that could damage it. The robot 150 would hold the system 100 at the top. In all cases the object 105 would be processed by a sequence of hammer 101 strikes that overlap and cover an entire processed area. Because the strikes overlap, and the opposing hammers 101 apply approximately the same force with each strike, the forces felt by the robot 150 are minimized or canceled out.

The deformation system 100 may select a hammer 101 including punch tip 110 for an object 105 to be worked on. The hammer 101 has two primary components, the punch tip 110 that interacts with the object 105 by impact and a mass that drives it. Punch tips 110 may be interchangeable, and the physical configuration of the mass may be optimized to control the force-time function delivered to the punch tip 110. Punch tips 110 may be elongated or roughly axisymmetric, with curved or flat ends. Example punch tips 100 are illustrated by the punch tips 110A-110D of FIG. 2A.

A punch tip 110 may be modified depending on the job to be done (i.e., the deformation to apply to the object 105). Typically, the major dimension of the hammer 101 end will correspond to the size of the feature to be processed. For example, if a weld fillet is to be processed, the width may correspond to the fillet width, or if a corner has a radius of curvature, the tool may fit this with some possible overlap of non-root geometry. These are much larger than the working zones of typical hammer-peen ends. The width w will usually correspond to (or be slightly larger than) the width of a fillet radius, width of a weld pass or be optimized to reduce the amount of time required to process the object 105. The depth of the processed zone, or interaction volume 107, will usually be similar to the punch width w this also sets a desired punch width. In most applications, several overlapping impacts of the hammer 101 will typically be used to fully process the object 105.

The deformation system 100 may select an impact energy 104 for the hammer 101. The hammer 101 and tip 110 have a kinetic energy described by the equation E=mv². A designed process energy per strike can be estimated by the equation (1):

$${E}_{k}^{d} = \frac{F}{4} {w}^{3} \overline{σ} \overline{ε} \qquad ( 1 )$$

Where Eₖ^{d} is the design level of kinetic energy required, v is the velocity of the hammer 101, m is the mass of the hammer 101, w is the nominal width of the hammer 101 end, the volume of is approximated by w³, F is a factor (typically 3-10) that governs the translation of kinetic energy to plastic deformation, and E is the effective plastic strain that the hammering process will impart. This will generally be greater than 0.02 and less than 0.5. Large strains will impose large deformations on the material. σ̅ is the effective flow stress of the material, equal to the uniaxial flow stress half the effective strain. Note that the effective stress and strain for an object 105 may be defined in books on metal forming and plasticity.

The process needed for a deformation of an object 105 may be determined by first determining how much strain and penetration depth are needed for the deformation. From this, the amount of energy needed for the deformation can be estimated. Then, based on the mass of the available hammers 101, the speed needed for a hammer 101 be selected. The particular speed needed may be dependent on the mass of the hammer 101 that is selected.

The general approach is based on studies on hardness, and dynamic hardness. From this we have learned that a pressure, usually about 3 times the flow stress, is required for significant deformation. This is the origin of the factor F above. This equation is based on work on the dynamic hardness of metals and the observation that the deformed depth is roughly equal to the radius of the indenter (w/2) and as the impactor speed increases, the factor F increases. Work dissipated over that volume is the product of nominal effective stress, effective strain, and the volume of the work area. As rough numbers for a typical scenario of mild steel at room temperature, where a 1 cm wide flat weld root is being processed,

$$F = 5$$

$$w = \text{.01} m$$

$$\overline{σ} = 200 MPa$$

$$\overline{ε} = 0.05$$

Providing a target impact energy of 12.5 J per stroke or impact. This is the kinetic energy carried in a 1 kg hammer 101 at a speed of 5 m/s. If that mass were to be accelerated over a 5 cm distance, this would require a force of 250 N (about 56 pounds). This is well within the load limits of many robot systems. High speeds or masses can require large reaction forces on the robot, and they are often avoided for this reason.

This is presented as a kinetic energy problem, but the deformation energy can also be imparted by a high force punch. In the case of opposed drives (i.e., FIG. 2B) no forces are transmitted to the robot 150. This ‘pincer-like’ approach is appropriate for wall-like features. For downward deformation (FIG. 2A) high forces are required. Using the example parameters above, the required pressure must be about 600 MPa over a 1 cm diameter circle, this becomes a force of 47,000 Nt (or about 10,000 pounds or 5 tons). Because the single kinetic strike is more versatile and only requires modest force, this is more versatile. For example, energy is force over distance. By using a longer distance to accelerate the hammer 101, less force is felt by the robot 150. Because the hammer 101 is free-flying, little or no force is transmitted to the robot 150.

In some embodiments, the deformation system may also consider strain rate when determining impact energy. Strain rate is the increment in strain divided by time increment. As an estimate, we can use strain of deformation divided by contact time. Kinetic energy is chosen as a major design parameter. This can be made up by combinations of velocity and mass. There is also a well-developed area of shock physics, based on the high speed (usually >100 m/s) impact of solids. In shock conditions, peak pressure increases monotonically with impact pressure and is often nearly linearly related to impact pressure. This shock hardening may play a second-order role in modifying microstructure. The impact speed should also be large enough to induce plastic deformation. If this is done by shock mechanisms, the impact speed will be over about 10 m/s for most practical engineering material pairs of punch tip and workpiece material. The rigid-body deceleration of the hammer 101 may also produce plastic deformation at much lower impact speeds and this will be very effective at modifying microstructure. The computation of this minimum impact speed is more complicated and requires understanding the mass and compliance of the material holding system, and configuration of the hammer 101 mass. Minimum impact speeds that still induce plastic deformation in the workpiece can be less than 2 m/s and can be experimentally or analytically determined. Generally better results with respect to plastic deformation will take place with higher speeds versus larger masses to be driven and there will be an improved mechanical efficiency.

This process can also be carried out with low-speed mechanical or hydraulic presses at very low strain rates. In many cases the total strain level, rather than strain rate is primarily responsible for microstructural modification.

The deformation system 100 may further chose the drive mechanism 106 to use for the deformation of the object 105. There are many drive mechanisms 106 that may be used to drive or swing the hammers 101. These may include, but are not limited to, electromagnetic drives using both Lorentz forces (Electroimpact company etc.) and magnetically driven solenoid effects (Lourdes press, patents by George Meyerle), spring drives (LMC press), hydraulic drives (Cell Impact, Adia press from France), explosive drives, and high-speed mechanical cam drives. Each drive mechanism 106 may have its own advantages and disadvantages. The challenge that has presented itself in this development is that at high levels of kinetic energy per strike the equipment is often not mechanically robust and fails by fatigue. The two approaches that have proven to be commercially successful as dynamic impact systems are the relatively low-voltage Lorentz approach used commercially for dynamic riveting by Electroimpact and the high energy solenoid approach used by Lourdes/Netronics. In some embodiments, the solenoid drive mechanism 106 is the preferred type of drive mechanism 106.

In some embodiments, the robot 150 may guide or advance the deformation system with respect to the object 105. In such embodiments, the object 105 may be placed on a fixed base, such as a cast iron base, and the robot 150 may provide the relative position between the hammer 101 and workpiece 105 and may incrementally advance the hammer 101 along features of the object 105 or a surface of the object 105.

In such a case, the robot 150 has maximum forces that should not be exceeded. Forces are easily moderated if, as in the example above, the hammer 101 is accelerated over a distance and in essentially free flight prior to impact with the object 105. As energy is dissipated upon impact, and as it may be axially uncoupled from the robot by linear bearings, forces to the robot may be minimal. Some damping may be needed in the case the hammer elastically rebounds from the workpiece. This is a preferred method to protect the robot 150. The opposed drive mechanism of FIG. 2B also protects the robot 150. Using modest forces to impart kinetic energy to the tool, without transmitting excessive force to the robot is a key concept in this invention.

For shorter acceleration drives, the same principles that are used in recoilless rifles may be used to minimize forces on the robot 150, those are that the mass of the hammer 101 is significantly less than that of the driving element, and the driving element may be on a damped slide relative to the robot 150. This may not be needed if longer acceleration lengths are used.

Together these design principles can be used to couple a hammer 101, effective for processing materials via plastic deformation to a robot 150 used for spatial control for sequential blows. There are several possible applications for such a deformation system 100. They include:
Reduction in porosity due to the nominally compressive plastic deformation.
Plastic strain can strain harden, and induce plastic deformation.
Plastic strain can break up large and blocky solidification features
Residual stress can be reduced or controlled to optimize fatigue performance.
Overall component dimensions and shape can be corrected by deformation in much the way blacksmiths use deformation to produce shape.
Surface features, ranging from smooth to intentional roughness can be induced by appropriate hammer tips.

This method may be particularly important used with weld deposits and can be used after each pass or a large body has been built up for all the reasons mentioned above. Also, if performed while the weld is still hot, flow stresses are reduced, and this may be more effective. Also, if a wall-like feature is to be developed, one could repeatedly alternate deformation in the downward direction (FIG. 2A) and squeeze normal to the height (FIG. 2B). This repeated redundant deformation work, may be important to develop plastic strain and is the basis for strong thermomechanical processing.

This method, applied to joining two dissimilar metals, with possibly a third filler metal and then subsequent incremental mechanical working and heat treating is an effective way to produce components with locally varied material chemistry. This can be an important starting point for high-performance components.

Likely the best way to develop such a system is to use the solenoid-drive system based on ferromagnetic attraction of an iron core into an energized solenoid. This approach can be very robust, lightweight, low-cost and effective.

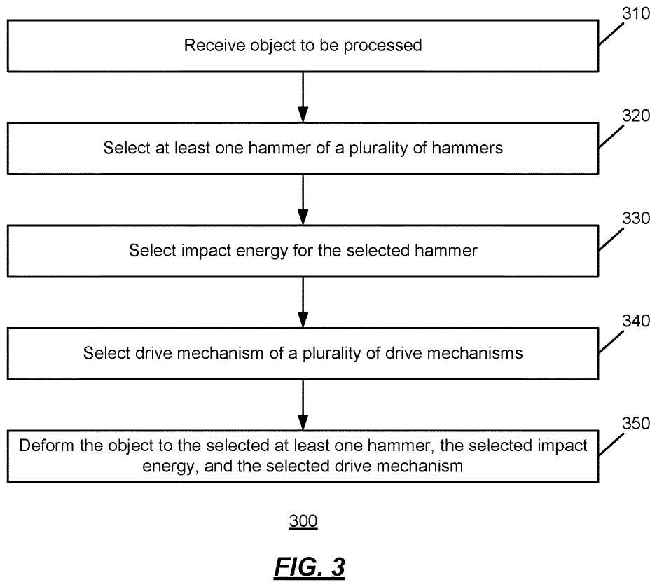

FIG. 3 is an illustration of an example method 300 for local plastic deformation. The method 300 may be implemented by one or more of the deformation system 100, the robot 150, or the computing device 400.

At 310, an object to be processed is received. The object 105 may be received by the deformation system 100. The object 105 may be plastic object 105, or a metal object 105. Other types of objects 105 may be supported. The object may have been selected to receive a deformation of modification. Example deformations may include deformations to improve shape, deformations to improve surface finish or improve material properties such as increased hardness, or deformations to reduce porosity or to induce residual stress.

At 320, at least one hammer of a plurality of hammers is selected. The at least one hammer 101 may be selected by the deformation system. Selecting the hammer 101 may include selecting the weight of the hammer 101 and a size of the interaction volume 107 of the hammer 101 with respect to the object 105. In addition, selecting the hammer 101 may include selecting a punch tip 110 for the hammer 101.

At 330, an impact energy for the selected hammer is selected. The impact energy 104 may be selected based on the hammer 101, properties of the object 105, and the desired deformation or deformations for the object 105. The impact energy 104 may be determined using the equation 1 described previously. Other methods for calculating impact energy may be used.

At 340, a drive mechanism of a plurality of drive mechanisms is selected. The drive mechanism 106 may be selected by the deformation system 100 based on information such as the desired impact energy 104, properties of the hammer 101, and the desired deformation for the object 105. In some embodiments, the drive mechanism 106 is a solenoid-based drive mechanism 106.

At 350, the object is deformed by the selected hammer and selected drive mechanism at the selected impact energy. The object 105 may be deformed by the robot 150 moving the deformation system 100 including one or more hammers 101 with respect to the object 105. Depending om the embodiment, the object 105 may be held in fixed position while the robot 150 moves the system 100 with respect to the robot 150.

FIG. 4 shows an exemplary computing environment in which example embodiments and aspects may be implemented. The computing device environment is only one example of a suitable computing environment and is not intended to suggest any limitation as to the scope of use or functionality.

Numerous other general purpose or special purpose computing devices environments or configurations may be used. Examples of well-known computing devices, environments, and/or configurations that may be suitable for use include, but are not limited to, personal computers, server computers, handheld or laptop devices, multiprocessor systems, microprocessor-based systems, network personal computers (PCs), minicomputers, mainframe computers, embedded systems, distributed computing environments that include any of the above systems or devices, and the like.

Computer-executable instructions, such as program modules, being executed by a computer may be used. Generally, program modules include routines, programs, objects, components, data structures, etc. that perform particular tasks or implement particular abstract data types. Distributed computing environments may be used where tasks are performed by remote processing devices that are linked through a communications network or other data transmission medium. In a distributed computing environment, program modules and other data may be located in both local and remote computer storage media including memory storage devices.

With reference to FIG. 4, an exemplary system for implementing aspects described herein includes a computing device, such as computing device 400. In its most basic configuration, computing device 400 typically includes at least one processing unit 402 and memory 404. Depending on the exact configuration and type of computing device, memory 404 may be volatile (such as random access memory (RAM)), non-volatile (such as read-only memory (ROM), flash memory, etc.), or some combination of the two. This most basic configuration is illustrated in FIG. 4 by dashed line 406.

Computing device 400 may have additional features/functionality. For example, computing device 400 may include additional storage (removable and/or non-removable) including, but not limited to, magnetic or optical disks or tape. Such additional storage is illustrated in FIG. 4 by removable storage 408 and non-removable storage 410.

Computing device 400 typically includes a variety of computer readable media. Computer readable media can be any available media that can be accessed by the device 400 and includes both volatile and non-volatile media, removable and non-removable media.

Computer storage media include volatile and non-volatile, and removable and non-removable media implemented in any method or technology for storage of information such as computer readable instructions, data structures, program modules or other data. Memory 404, removable storage 408, and non-removable storage 410 are all examples of computer storage media. Computer storage media include, but are not limited to, RAM, ROM, electrically erasable program read-only memory (EEPROM), flash memory or other memory technology, CD-ROM, digital versatile disks (DVD) or other optical storage, magnetic cassettes, magnetic tape, magnetic disk storage or other magnetic storage devices, or any other medium which can be used to store the desired information and which can be accessed by computing device 400. Any such computer storage media may be part of computing device 400.

Computing device 400 may contain communication connection(s) 412 that allow the device to communicate with other devices. Computing device 400 may also have input device(s) 414 such as a keyboard, mouse, pen, voice input device, touch input device, etc. Output device(s) 416 such as a display, speakers, printer, etc. may also be included. All these devices are well known in the art and need not be discussed at length here.

It should be understood that the various techniques described herein may be implemented in connection with hardware components or software components or, where appropriate, with a combination of both. Illustrative types of hardware components that can be used include Field-programmable Gate Arrays (FPGAs), Application-specific Integrated Circuits (ASICs), Application-specific Standard Products (ASSPs), System-on-a-chip systems (SOCs), Complex Programmable Logic Devices (CPLDs), etc. The methods and apparatus of the presently disclosed subject matter, or certain aspects or portions thereof, may take the form of program code (i.e., instructions) embodied in tangible media, such as floppy diskettes, CD-ROMs, hard drives, or any other machine-readable storage medium where, when the program code is loaded into and executed by a machine, such as a computer, the machine becomes an apparatus for practicing the presently disclosed subject matter.

Although exemplary implementations may refer to utilizing aspects of the presently disclosed subject matter in the context of one or more stand-alone computer systems, the subject matter is not so limited, but rather may be implemented in connection with any computing environment, such as a network or distributed computing environment. Still further, aspects of the presently disclosed subject matter may be implemented in or across a plurality of processing chips or devices, and storage may similarly be affected across a plurality of devices. Such devices might include personal computers, network servers, and handheld devices, for example.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed is:

1. A method for local plastic deformation comprising:
receiving an object to be processed by a computing device;
selecting at least one hammer of a plurality of hammers by the computing device;
selecting an impact energy for the selected at least one hammer by the computing device;
selecting a drive mechanism of a plurality of drive mechanisms by the computing device; and
deforming the object using the at least one hammer, the selected impact energy, and the selected dive mechanism by the computing device.

2. The method of claim 1, wherein selecting the at least one hammer comprises selecting a mass and a punch tip for the at least one hammer.

3. The method of claim 2, wherein the selecting the punch tip comprises selecting the punch tip based on a size of the object.

4. The method of claim 1, further comprising selecting the impact energy based on a flow stress of the object, an amount of deformation desired, and a size and a geometry of a hammer tip.

5. The method of claim 1, wherein the drive mechanism comprises a solenoid, pneumatic drive, linear motor, or a rotary motor.

6. The method of claim 1, wherein selecting the at least one hammer comprises selecting two hammers.

7. The method of claim 1, further comprising selecting a robot based on the selected drive mechanism and using the robot to control the location of the hammer impact.

8. The method of claim 7, wherein the robot determines a deformation zone where to deform the object using the at least one hammer, the selected impact energy, and the selected dive mechanism.

9. The method of claim 7, wherein the object is deformed without transmitting large forces to the robot.

10. A system local plastic deformation comprising:
one or more processors;
a computer-readable medium with computer-executable instructions stored thereon that when executed by the one or more processors cause the one or more processors to:
receive an object to be processed;
select at least one hammer of a plurality of hammers;
select an impact energy for the selected at least one hammer;
select a drive mechanism of a plurality of drive mechanisms; and
deform the object using the at least one hammer, the selected impact energy, and the selected dive mechanism.

11. The system of claim 10, wherein selecting the at least one hammer comprises selecting a mass and a punch tip for the at least one hammer.

12. The system of claim 11, wherein the selecting the punch tip comprises selecting the punch tip based on a size of the object and characteristics of the deformation desired.

13. The system of claim 10, further comprising selecting the impact energy based on a flow stress of the object, a volume of a material of the object, and a desired strain level desired.

14. The system of claim 10, wherein the drive mechanism comprises a solenoid, pneumatic drive, linear motor, or a rotary motor.

15. The system of claim 10, wherein selecting the at least one hammer comprises selecting two hammers.

16. The system of claim 10, further comprising selecting a robot based on the selected drive mechanism and deforming the plastic object by the selected robot.

17. The system of claim 16, wherein the robot determines a deformation zone where to deform the object using at least one hammer, the selected impact energy, and the selected dive mechanism.

18. A non-transitory computer-readable medium with computer-executable instructions stored thereon that when executed by the one or more processors cause the one or more processors to:
receive an object to be processed;
select at least one hammer of a plurality of hammers;
select an impact energy for the selected at least one hammer;
select a drive mechanism of a plurality of drive mechanisms; and
deform the object using the at least one hammer, the selected impact energy, and the selected dive mechanism.

19. The computer-readable medium of claim 18, wherein selecting the at least one hammer comprises selecting a mass and a punch tip for the at least one hammer.

20. The computer-readable medium of claim 18, further comprising selecting the impact energy based on a flow stress of the object.
